(19) United States
(12) Patent Application Publication
(10) Pub. No.: US 2026/0372135 A1
(43) Pub. Date: Nov. 19, 2026

(54) ELECTRONIC DEVICES AND METHODS OF MANUFACTURING ELECTRONIC DEVICES

(71) Applicant: Amkor Technology Singapore Holding Pte. Ltd., Singapore (SG)

(72) Inventor: David Hiner, Chandler, AZ (US)

(21) Appl. No.: 19/209,228

(22) Filed: May 15, 2025

(51) Int. Cl. H10W 70/65; H10W 42/00; H10W 70/60; H10W 74/10; H10W 90/00

(52) U.S. Cl. CPC H10W 70/65; H10W 42/121; H10W 70/611; H10W 74/121; H10W 90/701

(57) ABSTRACT

An electronic device can include a lower substrate, an upper substrate, a bridge between the lower substrate and the upper substrate, a first electronic component, and a second electronic component. The bridge can include a bridge die, bridge through-interconnects, a bridge signal distribution structure, bridge upper interconnects, bridge lower interconnects, and a bridge mold layer. The bridge through-interconnects can pass vertically through the bridge die. The bridge signal distribution structure can be coupled to upper ends of the bridge through-interconnects. The bridge mold layer can cover the bottom side of the bridge die and laterally surround the bridge lower interconnects. The first electronic component can be electrically coupled to the bridge signal distribution structure via the upper substrate. The second electronic component can be electrically coupled to first electronic component via the upper substrate and the bridge signal distribution structure. Other examples and related methods are also disclosed herein.

### TECHNICAL FIELD

The present disclosure relates, in general, to electronic devices, and more particularly, to electronic devices and methods for manufacturing electronic devices.

### BACKGROUND

Prior electronic packages and methods for forming electronic packages are inadequate, resulting in, for example, excess cost, decreased reliability, relatively low performance, or package sizes that are too large. Further limitations and disadvantages of conventional and traditional approaches will become apparent to one of skill in the art, through comparison of such approaches with the present disclosure and reference to the drawings.

### BRIEF DESCRIPTION OF THE DRAWINGS

FIG. 1 shows a cross-sectional view of an example electronic device.

FIGS. 2A to 2F show cross-sectional views of an example method for manufacturing a bridge of the example electronic device of FIG. 1.

FIG. 3A shows a cross-section view of an example bridge where the bridge mold layer does not cover lower ends of the bridge through-interconnects.

FIG. 3B shows a cross-section view of an example bridge where the bridge mold layer covers lower ends of the bridge through-interconnects.

FIG. 3C shows a cross-section view of an example bridge where the bridge die includes integrated circuit devices.

FIG. 3D shows a cross-section view of an example bridge that includes both a bridge upper signal distribution structure and a bridge lower signal distribution structure.

FIGS. 4A to 4J show cross-sectional views of an example method for manufacturing the example electronic device of FIG. 1.

FIG. 5 shows a cross-sectional view of an example electronic device that includes the electronic device of FIG. 1 as an electronic module.

FIG. 6A shows a cross-sectional view of an example electronic device that includes multiple bridges.

FIG. 6B shows a cross-sectional view of an example electronic device that includes the electronic device of FIG. 6A as an electronic module.

### DESCRIPTION

The following discussion provides various examples of electronic devices and methods of manufacturing electronic devices. Such examples are non-limiting, and the scope of the appended claims should not be limited to the particular examples disclosed. In the following discussion, the terms “example” and “e.g.” are non-limiting.

The figures illustrate the general manner of construction, and descriptions and details of well-known features and techniques can be omitted to avoid unnecessarily obscuring the present disclosure. In addition, elements in the drawing figures are not necessarily drawn to scale. For example, the dimensions of some of the elements in the figures can be exaggerated relative to other elements to help improve understanding of the examples discussed in the present disclosure. The same reference numerals in different figures denote the same elements.

The term “and/or” means any one or more of the items in the list joined by “and/or”. As an example, “x and/or y” means any element of the three-element set {(x), (y), (x, y)}. As another example, “x, y, and/or z” means any element of the seven-element set {(x), (y), (z), (x, y), (x, z), (y, z), (x, y, z)}.

The terms “includes,” “comprising,” “includes,” and “including” are “open ended” terms and specify the presence of stated features, but do not preclude the presence or addition of one or more other features.

The terms “first,” “second,” “third,” etc. can be used herein to describe various elements, and the elements described using these terms should not be limited by the “first,” “second,” “third,” etc. The terms “first,” “second,” “third,” etc. are only used to distinguish one element from another. Thus, for example, a first element discussed in this disclosure could be termed a second element without departing from the teachings of the present disclosure.

Unless specified otherwise, the term “coupled” can be used to describe two elements directly contacting each other or describe two elements indirectly coupled by one or more other elements. For example, if element A is coupled to element B, then element A can be directly contacting element B or indirectly coupled to element B by an intervening element C. Similarly, the terms “over” or “on” can be used to describe two elements directly contacting each other or describe two elements indirectly coupled by one or more other elements. As used herein, the term “coupled” can refer to an electrical coupling or a mechanical coupling.

Also, it should be understood that any numerical range or list of numerical values recited herein is intended to include all sub-ranges subsumed therein. For example, a range of “1 to 10” is intended to include any and all sub-ranges between and including the recited minimum value of 1 and the recited maximum value of 10, that is, all sub-ranges beginning with a minimum value equal to or greater than 1 and ending with a maximum value equal to or less than 10, and all sub-ranges in-between, e.g., 1 to 6.3, or 5.5 to 10, or 2.7 to 6.1.

An example electronic device can include a lower substrate, an upper substrate, a bridge between the lower substrate and the upper substrate, a first electronic component, and a second electronic component. The bridge can include a bridge die, bridge through-interconnects, a bridge signal distribution structure, bridge upper interconnects, bridge lower interconnects, and a bridge mold layer. The bridge through-interconnects can pass vertically through the bridge die. The bridge signal distribution structure can be coupled to upper ends of the bridge through-interconnects. The bridge mold layer can cover the bottom side of the bridge die and laterally surround the bridge lower interconnects. The first electronic component can be electrically coupled to the bridge signal distribution structure via the upper substrate. The second electronic component can be electrically coupled to first electronic component via the upper substrate and the bridge signal distribution structure.

An example method of manufacturing an electronic device can include providing a bridge that includes a bridge die, bridge through-interconnects, a bridge signal distribution structure, bridge upper interconnects, bridge lower interconnects, a bridge mold layer, and a bridge die attach film. The bridge through-interconnects can pass vertically through the bridge die. The bridge signal distribution structure can be coupled to upper ends of the bridge through-interconnects. The bridge mold layer can cover the bottom side of the bridge die and laterally surround the bridge lower interconnects. The method can include encapsulating the bridge in a lower encapsulant having a lower encapsulant bottom side and a lower encapsulant top side such that the lower encapsulant covers the bridge upper interconnects. The method can also include removing an upper portion of the lower encapsulant to expose upper ends of the bridge upper interconnects, and providing an upper substrate over the lower encapsulant such that a upper substrate conductive structure is electrically coupled to the upper ends of the bridge upper interconnects. Further, the method can include providing a first electronic component and a second electronic component on the upper substrate such that the first electronic component and the second electronic component are electrically coupled to each other via the upper substrate and the bridge. The method can further include removing a lower portion of the lower encapsulant, the bridge die attach film, a lower portion of the bridge mold layer, and a lower portion of the bridge lower interconnects to expose lower ends of the bridge lower interconnects, and providing a lower substrate covering a bottom side of the lower encapsulant and electrically coupled to the lower ends of the bridge lower interconnects.

Other examples are included in the present disclosure. Such examples can be found in the figures, in the claims, or in the description of the present disclosure.

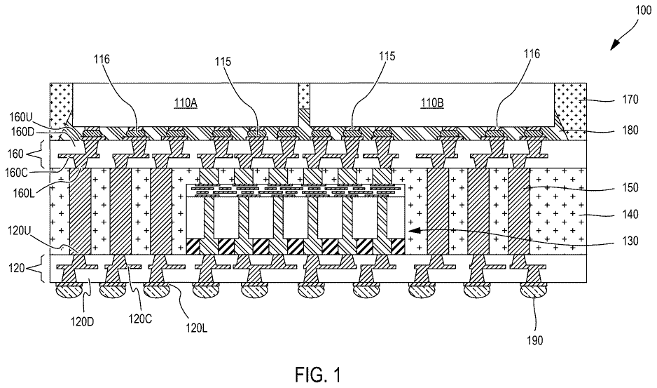

FIG. 1 shows a cross-sectional view of an example electronic device 100. As shown, the electronic device 100 can include one or more electronic components 110A, 110B, a lower substrate 120, one or more bridges 130, a lower encapsulant 140, one or more internal interconnects 150, and an upper substrate 160. In some examples, the electronic device 100 can also include an upper encapsulant 170, an underfill 180, and lower substrate interconnects 190.

Electronic component first interconnects 115 and electronic component second interconnects 116 can be included along a bottom side of each electronic component 110A, 110B. The electronic component first interconnects 115 and/or the electronic component second interconnects 116 can couple the respective electronic component 110A, 110B to upper substrate upper terminals 160U. In particular, the electronic component first interconnect 115 can electrically couple the electronic components 110A, 110B to one or more bridges 130 via one or more of the upper substrate upper terminals 160U. Similarly, the electronic component second interconnects 116 can couple their respective electronic component 110A, 110B to one or more internal interconnects 150 via one or more of the upper substrate upper terminals 160U.

The one or more bridges 130 can include conductive paths which electrically couple the first electronic component 110A and the second electronic components 110B to one another via their respective electronic component first interconnects 115 and the upper substrate 160. Further, the one or more bridges 130 can include conductive paths which electrically couple the first electronic component 110A and the second electronic component 110B to the lower substrate 120. In this manner, the electronic component first interconnects 115 can electrically couple the first electronic components 110A and the second electronic components 110B to each other via the upper substrate 160 and the one or more bridges 130. Further, the electronic component first interconnects 115 can electrically couple the first electronic components 110A and the second electronic components 110B to the lower substrate 120 via the upper substrate 160 and the one or more bridges 130.

In various examples, the electronic component second interconnects 116 can couple their respective electronic component 110A, 110B to the internal interconnects 150 via the upper substrate 160. As shown, upper ends of the internal interconnects 150 can be mechanically and electrically coupled to the upper substrate 160 and lower ends of the internal interconnects can be mechanically and electrically coupled to the lower substrate 120. Thus, the first electronic components 110A and the second electronic components 110B can be electrically coupled to the lower substrate 120 via their respective electronic component second interconnects 116, the upper substrate 160, and the internal interconnects 150.

In accordance with various examples, the electronic component first interconnects 115 for coupling the electronic components 110A, 110B to the one or more bridges 130 can have a narrow (or first) pitch. Conversely, the electronic component second interconnects 116 for coupling the electronic components 110A, 110B to the lower substrate 120 via the internal interconnects 150 can have a wide (or second pitch). In particular, the second width and/or the second pitch of the electronic component second interconnects 116 can be greater than the first width and/or the first pitch of the electronic component first interconnects 115.

In some examples, each electronic component 110A, 110B can include or be referred to as a die, a chip, a package (e.g., an encapsulated device including one or more semiconductor die), an active device, or a passive device. Further, the electronic components 110A, 110B are shown mechanically and electrically coupled to the upper substrate 160 via their respective the electronic component first interconnects 115 and the electronic component second interconnects 116 in a face-down or flip-chip configuration. However, in some examples, the electronic components 110A, 110B can be electrically coupled to the upper substrate 160 via their respective electronic component first interconnects 115 and their respective electronic component second interconnects 116 in a face-up or wire bond configuration. In some examples, the overall thickness of each electronic component 110A, 110B can range from approximately 30 μm to approximately 800 μm, and the area of each electronic component 110A, 110B can range from approximately 0.5 mm×0.5 mm to approximately 100 mm×100 mm.

The upper substrate 160 can include an upper substrate dielectric structure 160D and an upper substrate conductive structure 160C. The upper substrate conductive structure 160C can include upper substrate upper terminals 160U and upper substrate lower terminals 160L.

The upper substrate dielectric structure 160D can include one or more dielectric layers and the upper substrate conductive structure 160C can include one or more conductive layers. In particular, the upper substrate dielectric structure 160D can include multiple dielectric layers that are alternately stacked or interleaved with one or more conductive layers of the upper substrate conductive structure 160C. Portions of the upper substrate conductive structure 160C located or otherwise exposed along a top side of the upper substrate 160 can be referred to as upper substrate upper terminals 160U. Portions of the upper substrate conductive structure 160C located or otherwise exposed along a bottom side of the upper substrate 160 can be referred to as upper substrate lower terminals 160L.

The upper substrate dielectric structure 160D can include an electrically insulating material such as polyimide (PI), benzocyclobutene (BCB), polybenzoxazole (PBO), resin, or Ajinomoto buildup film (ABF) and can be formed by spin coating, spray coating, dip coating, rod coating, PVD, CVD, or any other suitable formation method. Upper substrate dielectric structure 160D can be provided such that upper substrate dielectric structure 160D can be positions over, can cover, and/or can be coupled to a top side of the lower encapsulant 140, the top side of each bridge 130, and the top side of each internal interconnects 150.

The upper substrate conductive structure 160C can be interleaved with the upper substrate dielectric structure 160D. The upper substrate conductive structure 160C can be in contact with and electrically coupled to the internal interconnects 150 and to the bridge 130. The upper substrate conductive structure 160C can include one or more conductive layers defining signal distribution elements (e.g., traces, vias, pads, conductive paths, or UBM). The upper substrate conductive structure 160C can provide signal and power distribution in the vertical and horizontal directions through upper substrate 160. The upper substrate conductive structure 160C can include copper, gold, silver, aluminum, nickel, palladium, titanium, tungsten, or any other suitable conductive material.

In some examples, the upper substrate 160 can include an upper substrate dielectric structure 160D having two dielectric layers and an upper substrate conductive structure 160C having two conductive layers. However, the quantity of layers constituting the upper substrate dielectric structure 160D and/or the quantity of layers constituting the upper substrate conductive structure 160C can be fewer than or more than two. One or more conductive layers or elements of the upper substrate conductive structure 160C can be interleaved with one or more dielectric layers of the upper substrate dielectric structure 160D. The upper substrate upper terminals 160U and the upper substrate lower terminals 160L can be provided above and below the upper substrate 160 and can be spaced apart from each other in the row and/or column directions.

In some examples, the upper substrate 160 can include a redistribution layer (“RDL”) substrate. RDL substrates can include one or more conductive layers and one or more dielectric layers. RDL substrates can be formed (a) layer by layer over an electronic component to which the RDL substrate is to be coupled, or (b) layer by layer over a carrier that can be entirely removed or at least partially removed after the electronic component and the RDL substrate are coupled together. RDL substrates can be manufactured layer by layer as a wafer-level substrate on a round wafer in a wafer-level process, and/or as a panel-level substrate on a rectangular or square panel carrier in a panel-level process. RDL substrates can be formed in an additive buildup process and can include one or more dielectric layers alternatingly stacked with one or more conductive layers that define respective conductive redistribution patterns or traces configured to collectively (a) fan-out electrical traces outside the footprint of the electronic component, and/or (b) fan-in electrical traces within the footprint of the electronic component.

The lower substrate 120 can include a lower substrate dielectric structure 120D and a lower substrate conductive structure 120C. The lower substrate conductive structure 120C can include lower substrate upper terminals 120U and lower substrate lower terminals 120L.

The lower substrate dielectric structure 120D can include one or more dielectric layers and the lower substrate conductive structure 120C can include one or more conductive layers. In particular, the lower substrate dielectric structure 120D can include multiple dielectric layers that are alternately stacked or interleaved with one or more conductive layers of the lower substrate conductive structure 120C.

The lower substrate dielectric structure 120D can include one or more dielectric layers and the lower substrate conductive structure 120C can include one or more conductive layers. In particular, the lower substrate dielectric structure 120D can include multiple dielectric layers that are alternately stacked or interleaved with one or more conductive layers of the lower substrate conductive structure 120C. Portions of the lower substrate conductive structure 120C located or otherwise exposed along a top side of the lower substrate 120 can be referred to as lower substrate upper terminals 120U. Portions of the lower substrate conductive structure 120C located or otherwise exposed along a bottom side of the lower substrate 120 can be referred to as lower substrate lower terminals 120L. The lower substrate upper terminals 120U can be mechanically and/or electrically coupled to the bridge 130 and/or the internal interconnects 150. The lower substrate lower terminals 120L can be mechanically and/or electrically coupled to the lower substrate interconnects 190.

In some examples, the lower substrate 120 can include a lower substrate dielectric structure 120D having two dielectric layers and a lower substrate conductive structure 120C having two conductive layers. However, the quantity of layers constituting the lower substrate dielectric structure 120D and/or the quantity of layers constituting the lower substrate conductive structure 120C can be fewer than or more than two. Further, the lower substrate 120 can have elements, features, materials, and/or manufacturing methods that are similar to or the same as those of the upper substrate 160 and/or any other substrate or signal distribution structure described herein.

The lower encapsulant 140 can protect the one or more bridges 130 and the internal interconnects 150 from external elements. To this end, the lower encapsulant 140 can cover, can contact, and/or surround the one or more bridges 130 and the internal interconnects 150. In particular, the lower encapsulant 140 in some examples can contact and/or laterally surround lateral sides of each bridge 130, can contact and/or cover a top side of each bridge 130, can contact and/or laterally surround lateral sides of each internal interconnects 150. Furthermore, the lower encapsulant 140 can mechanically couple the lower substrate 120 to the upper substrate 160. To this end, a top side of the lower encapsulant 140 can contact, can cover, and/or can be coupled to a bottom side of the upper substrate 160. Similarly, a bottom side of the lower encapsulant 140 can contact, can cover, and/or can be coupled to a top side of the lower substrate 120.

In some examples, the lower encapsulant 140 can include or be referred to as a body or a molding. For example, the lower encapsulant 140 can include an epoxy mold compound, resin, organic polymer with inorganic filler, a curing agent, a catalyst, a coupling agent, a colorant, or a flame retardant, and can be formed by compression molding, transfer molding, liquid body molding, vacuum lamination, paste printing, or film-assisted molding. The thickness of the lower encapsulant 140 can range from approximately 20 μm to approximately 800 μm.

In accordance with various examples, the internal interconnects 150 can mechanically and/or electrically couple the lower substrate 120 to the upper substrate 160. In particular, an upper end of each internal interconnect 150 can be coupled to the upper substrate conductive structure 160C and a lower end of each internal interconnect 150 can be coupled to the lower substrate conductive structure 120C. In this manner, the internal interconnects 150 can provide electrical paths for data signals, power signals, and/or ground signals to traverse between the lower substrate 120 and the upper substrate 160.

In various examples, the internal interconnects 150 can be made of a conductive material such as, for example, copper, gold, silver, palladium, or nickel. The internal interconnects 150 can be provided in rows and/or columns. In some examples, the height (i.e., thickness) of the internal interconnects 150 can range from approximately 20 μm to approximately 800 μm. The internal interconnects 150 can include or be referred to as vertical conductive structures such as pillars, posts, through mold vias (TMVs), copper core solder balls (CCBs), or solder balls, or copper cube columns (CCCs). In accordance with various examples, CCCs can include a plurality of vertical conductive structures (e.g., columns, pillars, posts, etc.) disposed in an insulating body, such as mold material (e.g., an epoxy mold compound, resin, organic polymer with inorganic filler, etc.).

The upper encapsulant 170 can protect the first electronic component 110A, the second electronic component 110B, and underfill 180 from external elements. In some examples, the upper encapsulant 170 can cover, can contact, and/or surround the electronic components 110A, 110B. In particular, in some examples, the upper encapsulant 170 can cover and/or contact a top side of each electronic component 110A, 110B, can contact and/or laterally surround lateral sides of each electronic components 110A, 110B, can cover and/or contact a top side of the upper substrate 160, and can cover, contact, and/or laterally surround a lateral sides of the underfill 180. In some examples, the upper encapsulant 170 can expose a top side of each electronic component 110A, 110B. In such examples, the top side of the upper encapsulant 170 can be coplanar with the top side of each electronic component 110A, 110B. In various examples, the upper encapsulant 170 can have elements, features, materials, and/or manufacturing methods that are similar to or the same as those of the lower encapsulant 140 and/or any other encapsulant described herein.

The underfill 180 can be provided between the upper substrate 160 and the first electronic components 110A. Further, the underfill 180 can be provided between the upper substrate 160 and the second electronic components 110B. In some examples, the underfill 180 can span the lateral space between the first electronic component 110A and its respective second electronic component 110B. The underfill 180 can be in contact with a bottom side of each first electronic component 110A and can be in contact with a bottom side of each second electronic component 110B. In some examples, the underfill 180 can be in contact with the electronic component interconnects 115. The underfill 180 can also be in contact with the top side of the upper substrate 160. The underfill 180 can help prevent the first electronic component 110A and/or the second electronic components 110B from being separated from the upper substrate 160 due to physical impacts and/or thermal impacts.

The underfill 180 can include or be referred to as a dielectric layer or a non-conductive paste and can be free of inorganic fillers. In some examples, the underfill 180 can include or be referred to as a capillary underfill (CUF), a nonconductive paste (NCP), a nonconductive film (NCF), an anisotropic conductive film (ACF), or an anisotropic conductive paste (ACP). In some examples, a separate underfill 180 can be omitted. In such examples, the upper encapsulant 170 can underfill the first electronic components 110A and the second electronic components 110B.

The lower substrate interconnects 190 can be coupled to and in contact with the lower substrate lower terminals 120L of the lower substrate conductive structure 120C. In some examples, the lower substrate interconnects 190 can include tin (NS), silver (Ag), lead (Pb), copper (Cu), Sn—Pb, Sn37—Pb, Sn95—Pb, Sn—Pb—Ag, Sn—Cu, Sn—Ag, Sn—Au, Sn—Bi, or Sn—Ag—Cu. For example, the lower substrate interconnects 190 can be provided through a reflow process after forming a conductive material including solder on lower substrate lower terminals 120L through a ball drop method. The lower substrate interconnects 190 can include or be referred to as conductive balls such as solder balls, conductive pillars such as copper pillars, or conductive posts having solder caps provided on copper pillars. In some examples, the sizes of each lower substrate interconnect 190 can range from approximately 0.5 μm to approximately 1000 μm.

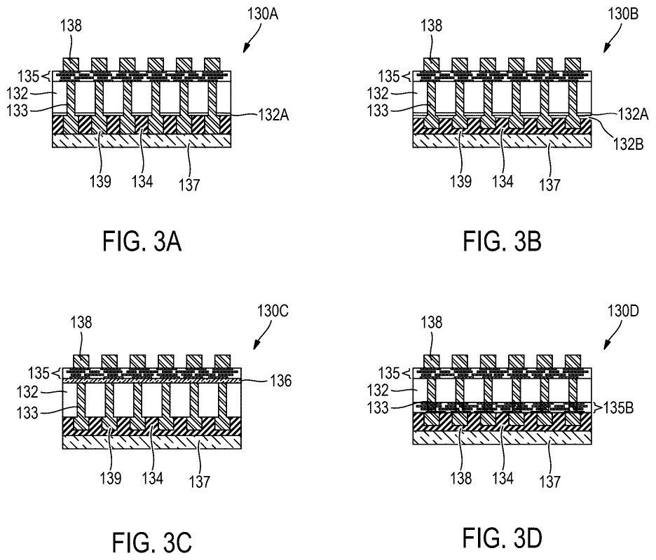

With reference to FIG. 1 and FIG. 3A, each of the one or more bridges 130 can include a bridge die 132 with bridge through-interconnects 133. Each bridge 130 can further include a bridge mold layer 134, a bridge signal distribution structure 135, bridge upper interconnects 138, and bridge lower interconnects 139.

The bridge die 132 of each bridge 130 can comprise a semiconductor die providing a bridge die top side, a bridge die bottom side, and bridge die lateral sides between the bridge die top side, and the bridge die bottom side. In various examples, the semiconductor die comprises a silicon die. However, other examples of the bridge die 132 can use a semiconductor die of other semiconductor materials (e.g., gallium arsenide (GaAs), indium phosphide (InP), etc.).

As shown, each bridge die 132 can include bridge through-interconnects 133 that pass vertically through the respective bridge die 132. In particular, an upper end of each bridge through-interconnect 133 can be exposed at a top side of its respective bridge die 132. In some examples, the upper end of each bridge through-interconnect 133 can be coplanar with the top side of its respective bridge die 132. Similarly, a lower end of each bridge through-interconnect 133 can be exposed at a bottom side of its respective bridge die 132. In some examples, the lower end of each bridge through-interconnect 133 can be coplanar with the bottom side of its respective bridge die 132.

In various examples, the bottom side of the bridge 130 can comprise one or more bridge lower dielectric layers 132A, 132B. In particular, the bridge 130 can include bridge silicon nitride (SiN) layer 132A that covers the bottom side of the bridge die 132 as shown in FIG. 3A. Further, the bridge 130 can include a bridge polyimide (PI) layer 132B that covers the bottom side of the bridge die 132 and/or the bridge SiN layer 132A as shown in FIG. 3B. While shown in the examples of FIGS. 3A and 3B, any examples of the bridges 130, 130A, 130B, 130C, 130D discussed herein can include one or more bridge lower dielectric layers. For such examples, the lower end of each bridge through-interconnect 133 can be coplanar with the bottom side of the lowermost layer of the one or more bridge lower dielectric layers (e.g., bridge SiN layer 132A or bridge PI layer 132B).

Further, each bridge through-interconnects 133 can have a width or diameter ranging from approximately 0.5 μm to approximately 200 μm. Moreover, the bridge through-interconnects 133 can be arranged with a pitch (i.e., spacing between adjacent bridge through-interconnects 133) ranging from approximately 0.5 μm to approximately 200 μm. In some examples, the bridge through-interconnects 133 can have a matrix arrangement with a uniform pitch. In other examples, the bridge through-interconnects 133 can be distributed unevenly such that certain sections include a greater quantity or a greater concentration of bridge through-interconnects 133 than other sections.

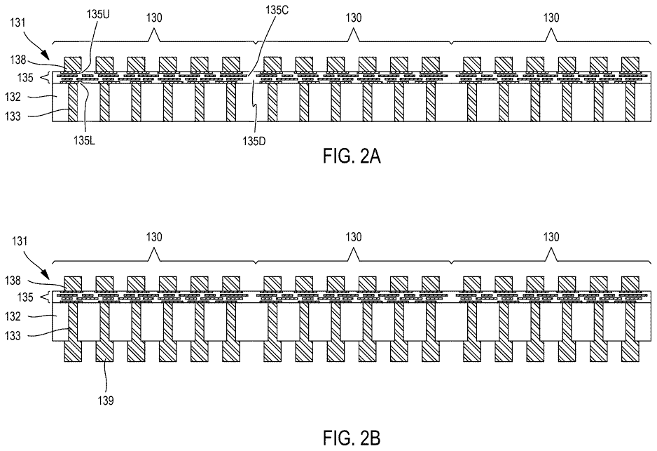

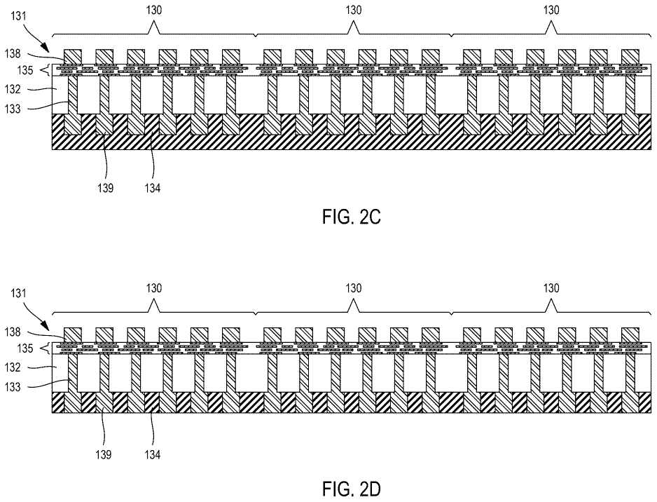

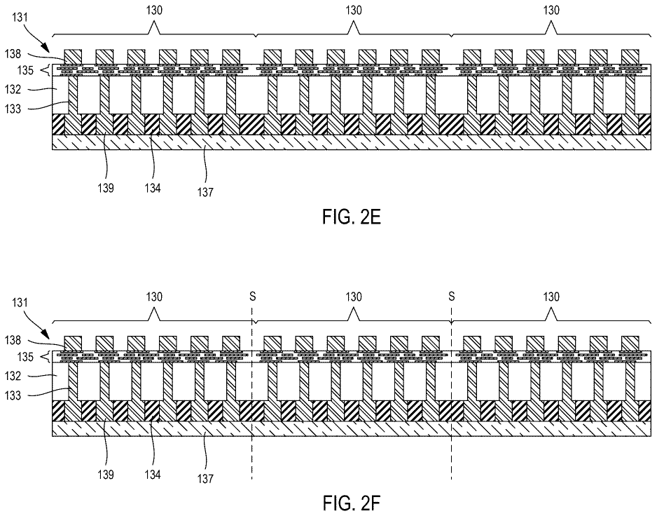

The bridge signal distribution structure 135 can be provided over, can be coupled to, and/or can cover the top side of its respective bridge die 132. Further, the bridge signal distribution structure 135 can be provided over, can be coupled to, and/or can cover the upper end of each bridge through-interconnect 133. In various examples, the bridge signal distribution structure 135 can include a bridge signal distribution dielectric structure 135D and a bridge signal distribution conductive structure 135C. See, e.g., FIG. 2A.

The bridge signal distribution dielectric structure 135D can include one or more dielectric layers made of a dielectric or insulating material interleaved between conductive layers of the bridge signal distribution conductive structure 135C. In some examples, the bridge signal distribution dielectric structure 135D can include one or more layers of inorganic dielectric material such as SiO2, SiCN, Si3N4. In some examples, the bridge signal distribution dielectric structure 135D can include one or more layers of organic dielectric material such as polyimide (PI), polymer, benzocyclobutene (BCB), polybenzoxazole (PBO), bismaleimide triazine (BT), Ajinomoto Buildup Film (ABF) or resin. The bridge signal distribution dielectric structure 135D can be provided by spin coating, spray coating, dip coating, rod coating, printing, oxidation, PVD, CVD, ALD, LPCVD, PECVD, and/or any other process known to one of ordinary skill in the art. In some examples, the thickness of bridge signal distribution dielectric structure 135D can range from approximately 0.5 μm to approximately 50 μm. In various examples, the thickness of bridge signal distribution dielectric structure 135D can refer to individual layers of bridge signal distribution dielectric structure 135D.

The bridge signal distribution conductive structure 135C can include one or more conductive layers defining signal distribution elements (e.g., traces, vias, pads, conductive paths, and/or UBMs) that are interleaved with dielectric layers of bridge signal distribution dielectric structure 135D. The one or more conductive layers of the bridge signal distribution conductive structure 135C can include or be referred to as traces, pads, vias, conductive paths, wire patterns, circuit patterns, redistribution layers (RDLs), and/or UBM. In some examples, the bridge signal distribution conductive structure 135C can include copper, aluminum, iron, nickel, gold, silver, palladium, titanium, and/or tin. The bridge signal distribution conductive structure 135C can be provided by electrolytic plating, electroless plating, sputtering, deposition such as PVD, CVD, MOCVD, ALD, LPCVD, or PECVD. The bridge signal distribution conductive structure 135C can distribute electrical signals in a vertical direction and a lateral direction through the bridge signal distribution structure 135.

In various examples, the bridge signal distribution conductive structure 135C can provide conductive paths having a narrower width and/or a finer pitch than conductive paths provided by the upper substrate conductive structure 160C. Similarly, the bridge signal distribution conductive structure 135C can provide conductive paths having a narrower width and/or a finer pitch than conductive paths provided by the lower substrate conductive structure 120C. In this manner, the bridge signal distribution structure 135 can provide denser routing of signals than provided by the lower substrate 120 and/or the upper substrate 160. In some examples, each conductive layer of the bridge signal distribution conductive structure 135C can have a thickness range from approximately 0.5 μm to approximately 20 μm.

The bridge upper interconnects 138 can be coupled to upper terminals 135U of the bridge signal distribution conductive structure 135C. The bridge upper interconnects 138 can include or be referred to as pads, bumps, pillars, conductive posts, or solder balls. The bridge upper interconnects 138 can include conductive material such as aluminum, copper, an aluminum alloy, a copper alloy, solder, etc. In some examples, each bridge upper interconnect 138 can have a thickness ranging from approximately 0.1 μm to approximately 100 μm and a width ranging from approximately 0.1 μm to approximately 200 μm. Further, the bridge upper interconnects 138 can be arranged with a pitch (i.e., spacing between adjacent bridge upper interconnects 138) ranging from approximately 0.1 μm to approximately 200 μm.

The bridge signal distribution conductive structure 135C can be coupled to the bridge through-interconnects 133 and to the bridge upper interconnects 138. For example, the upper terminals 135U of the bridge signal distribution conductive structure 135C can be coupled to the bridge upper interconnects 138 along the top side of the bridge signal distribution structure 135. Further, lower terminals 135L of the bridge signal distribution conductive structure 135C can be coupled to the upper ends of the bridge through-interconnects 133. The bridge signal distribution conductive structure 135C can electrically couple one or more of the bridge upper interconnects 138 to one or more of the bridge through-interconnects 133. In accordance with various examples, at least some of the bridge upper interconnects 138 are not electrically coupled to the bridge through-interconnects 133 and instead provide electrical connection between the first electronic component 110A and the second electronic component 110B.

The bridge lower interconnects 139 can be coupled to lower terminals 135L of the bridge signal distribution conductive structure 135C. More specifically, an upper end of each bridge lower interconnect 139 can be mechanically and electrically coupled to a lower end of a respective bridge through-interconnect 133. The bridge lower interconnects 139 can include or be referred to as pads, bumps, pillars, conductive posts, or solder balls. The bridge lower interconnects 139 can include conductive material such as aluminum, copper, an aluminum alloy, a copper alloy, solder, etc. In some examples, each bridge lower interconnect 139 can have a thickness ranging from approximately 0.1 μm to approximately 100 μm and a width ranging from approximately 0.1 μm to approximately 200 μm. Further, the bridge lower interconnects 139 can be arranged with a pitch (i.e., spacing between adjacent bridge lower interconnects 139) ranging from approximately 0.1 μm to approximately 200 μm.

The bridge mold layer 134 can contact and/or laterally surround the bridge lower interconnects 139. Further, the bridge mold layer 134 can cover and/or contact exposed portions of the bridge die bottom side. In some examples, the bridge mold layer 134 is thicker than the bridge lower interconnects 139 so as to cover the lower ends of the bridge lower interconnects 139 with a depth of molding material ranging from approximately 0.1 μm to approximately 100 μm. See, e.g., FIGS. 3B-3D. Thus, in such examples, the bridge mold layer 134 can have an overall thickness ranging from approximately 0.2 μm to approximately 200 μm. In various examples, the bridge mold layer 134 can include an epoxy mold compound, resin, organic polymer with inorganic filler, a curing agent, a catalyst, a coupling agent, a colorant, or a flame retardant, and can be formed by compression molding, transfer molding, liquid body molding, vacuum lamination, paste printing, or film-assisted molding. In some examples, the bridge mold layer 134 can use a different mold material than the mold material used for the lower encapsulant 140 and/or can use a different mold material than the mold material used for the upper encapsulant 170. In various examples, the bridge mold layer 134 can have elements, features, materials, and/or manufacturing methods that are similar to or the same as those of the lower encapsulant 140, the upper encapsulant 170, and/or any other encapsulant or mold layer described herein. In particular, the bridge mold layer 134 can use the same mold material used for the lower encapsulant 140 and/or the same mold material used for the upper encapsulant 170.

The bridge mold layer 134 can provide the bridge 130 with various benefits. For example, the bridge mold layer 134 can impart the bridge 130 with rigidity that aids in the placement and/or handling of the bridge 130. The bridge mold layer 134 can further aid a planarization process used to reveal lower ends of the bridge lower interconnects 139 and/or used to planarize the bottom side of the bridge 130. Furthermore, the bridge mold layer 134 can reduce ionic migration of metal ions into the bridge die 132 during a planarization process.

Turning now to FIGS. 2A to 2F, cross-sectional views of an exemplary method for manufacturing the bridge 130 are shown. In particular, FIGS. 2A-2F show a method in which multiple bridges 130 are formed from a single bridge wafer or panel (hereafter wafer) 131 that includes multiple, joined bridge dies 130. Such bridge wafer 131 is singulated to form multiple, separate bridges 130. However, it is contemplated and understood that each bridge 130 can be manufactured separately.

Turning now FIG. 2A, a cross-sectional view of a bridge wafer 131 is shown at an early stage of manufacture. In particular, the process at FIG. 2A can include providing a bridge wafer 131 that includes a semiconductor wafer (i.e., silicon wafer) with multiple, joined bridge dies 132. Further, each bridge die 132 can include bridge through-interconnects 133 (e.g., through-silicon/semiconductor vias (TSVs) that pass vertically through respective bridge dies 132. The bridge wafer 131 can also include joined, bridge signal distribution structures 135 over the joined bridge dies 132. In some examples, the bridge wafer 131 can be provided at FIG. 2A with bridge upper interconnects 138 pre-attached to a top side of the bridge signal distribution structures 135. In other examples, the bridge wafer 131 can arrive without the bridge upper interconnects 138. In such examples, providing the bridge wafer 131 at FIG. 2A can include attaching or otherwise providing bridge upper interconnects 138 along the top side of the bridge signal distribution structures 135.

In various examples, the bridge wafer 131 can include a semiconductor substrate or wafer (e.g., silicon or other semiconductor material wafer) that provides the bridge dies 132. The bridge dies 132 and bridge signal distribution structures 135 can be singulated from the semiconductor wafer at a later step to form individual bridges 130, each with its respective bridge die 132 of silicon or another semiconductor material and with its respective bridge signal distribution structure 135.

As shown, upper ends of the bridge through-interconnects 133 can be exposed at a top side of its respective bridge die 132 of the bridge wafer 131. In some examples, the upper end of each bridge through-interconnect 133 can be coplanar with the top side of its respective bridge die 132. Further, a bridge signal distribution structure 135 can be provided over, can be coupled to, and/or can cover the top side of each bridge die 132. In some examples, the bridge signal distribution structure 135 can be formed during a back-end-of-line (BEOL) process.

FIG. 2B shows a cross-sectional view of the bridge 130 at a later stage of manufacture. In particular, FIG. 2B depicts attaching, forming, and/or otherwise providing bridge lower interconnects 139 along a bottom side of the bridge dies 132. In accordance with various examples, the bridge lower interconnects 139 can be provided along the bottom side of the bridge dies 132 and coupled to the bridge through-interconnects 133. More specifically, an upper end of each bridge lower interconnect 139 can be mechanically and electrically coupled to a lower end of a respective bridge through-interconnect 133.

After providing the bridge lower interconnects 139 along the bottom side of the bridge die 132, a bridge mold layer 134 can be formed along the bottom side of the bridge die 132 which encapsulates the bridge lower interconnects 139 as shown in FIG. 2C. The bridge mold layer 134 can cover and/or contact exposed bottom side portions of the bridge die 132. Further, the bridge mold layer 134 can laterally surround and/or contact lateral sidewalls of each bridge lower interconnect 139. Moreover, the bridge mold layer 134 can cover and/or contact the lower end of each bridge lower interconnect 139. In some examples, the bridge mold layer 134 can cover the lower ends of the bridge lower interconnects 139 with a depth of molding material ranging from approximately 0.1 μm to approximately 200 μm. In various examples, the bridge mold layer 134 can include an epoxy mold compound, resin, organic polymer with inorganic filler, a curing agent, a catalyst, a coupling agent, a colorant, or a flame retardant, and can be formed by compression molding, transfer molding, liquid body molding, vacuum lamination, paste printing, or film-assisted molding.

As shown in FIG. 2D, a portion (e.g., lower portion as shown) of the bridge mold layer 134 can be removed by a general mechanical grinding and/or chemical etching of the bottom side of the bridge mold layer 134. In particular, such removal can expose lower ends of the lower bridge lower interconnects 139. Further, such removal can also remove a portion of the of each bridge lower interconnect 139. In some examples, the lower end of bridge lower interconnects 139 can be coplanar with a bottom side of the bridge mold layer 134 after such grinding and/or chemical etching. The bridge mold layer 134 can have an initial thickness ranging from approximately 20 μm to approximately 800 μm prior to removal and final thickness ranging from approximately 20 μm to approximately 800 μm.

As noted above, the bridge mold layer 134 can provide the bridge 130 with various benefits related to the removal process of FIG. 2D. In particular, the bridge mold layer 134 can impart the bridge 130 with rigidity and/or mechanical support that helps protect the bridge die 132 and/or the bridge lower interconnects 139 during a mechanical grinding of the bottom side of the bridge 130. Furthermore, the bridge mold layer 134 can provide the bridge die 132 with a protection layer that inhibits and/or reducing ionic migration into the bridge die 132. In particular, grinding and/or etching of the lower ends of the bridge lower interconnects 139 can result in ionic migration (e.g., copper ions) into the bridge die 132. Such ionic migration can negatively affect the operation of the bridge 130.

FIG. 2E shows a cross-sectional view of the bridge wafer 131 at a later stage of manufacture. In particular, FIG. 2E depicts the bridge wafer 131 after a bridge die attach film or tape 137 has been applied, formed, or otherwise provided along the bottom side of the bridge wafer 131. More specifically, a top side of the bridge die attach film 137 can cover and/or contact a bottom side of the bridge mold layer 134. Furthermore, the top side of the bridge die attach film 137 can cover and/or contact a lower end of each bridge lower interconnect 139.

As noted, the bridge wafer 131 can include multiple, joined bridges 130 with their respective bridge die 132, signal distribution structures 135, bridge mold layers 134, and bridge die attach film 137 also joined. As shown in FIG. 2F, the bridge wafer 131 can be singulated to provide individual, discrete bridges 130. Singulation can include cutting or sawing along saw streets S and through the signal distribution structures 135, bridge dies 132, mold layers 134, and bridge die attach films 137. Through the singulation process, the lateral sides of the signal distribution structure 135, the lateral sides of the bridge die 132, the lateral sides of the bridge mold layer 134, and the lateral sides of the bridge die attach film 137 of a respective bridge 130 can be coplanar. In various examples, the overall thickness of bridge 130 can range from approximately 10 μm to approximately 800 μm, and the area of the bridge 130 can range from approximately 0.5 mm (millimeter)×0.5 mm to approximately 70 mm×70 mm.

FIG. 3A depicts a bridge 130A manufactured per the process of FIGS. 2A-2F. As shown, the bridge 130A can include a bridge die 132, bridge through-interconnects 133, a bridge mold layer 134, a bridge signal distribution structure 135, a bridge die attach film 137, bridge upper interconnects 138, and bridge lower interconnects 139. FIGS. 3B-3D depict further example bridges 130B, 130C, 130D that can be manufactured per a process similar to the process of FIGS. 2A-2F.

In particular, FIG. 3B depicts a bridge 130B with covered bridge lower interconnects 139. In particular, the bridge 130B of FIG. 3B, like the bridge 130A of FIG. 3A, can include a bridge die 132, bridge through-interconnects 133, a bridge mold layer 134, a bridge signal distribution structure 135, a bridge die attach film 137, bridge upper interconnects 138, and bridge lower interconnects 139. However, unlike the bridge mold layer 134 of the bridge 130A shown in FIG. 3A, the bridge mold layer 134 of the bridge 130B shown in FIG. 3B can cover and/or contact lower ends of the bridge through-interconnects 133.

The structure of the bridge 130B can be achieved via various processes. However, in some examples, the bridge 130B can be formed via a process similar to the process of FIGS. 2A-2F, but with either skipping the removal process of FIG. 2D or modifying the removal process of FIG. 2D. For example, the removal process of FIG. 2D can be modified to remove less of the bridge mold layer 134 so that the bridge mold layer 134 continues to cover the lower ends of the bridge through-interconnects 133 after the removal process of FIG. 2D.

FIG. 3C depicts a variation of a bridge 130 with one or more bridge integrated circuit devices 136. In particular, the bridge 130C, like the bridge 130A of FIG. 3A, can include a bridge die 132, bridge through-interconnects 133, a bridge mold layer 134, a bridge signal distribution structure 135, a bridge die attach film 137, bridge upper interconnects 138, and bridge lower interconnects 139. However, the bridge 130C of FIG. 3C can further include one or more bridge integrated circuit devices 136 that are integrated into and/or otherwise formed along a front side, active side, or top side of the bridge die 132. Such bridge integrated circuit devices 136 can include active devices such as transistors, diodes, logic gates, etc. and/or passive devices such as resistors, deep trench capacitors, inductors, etc.

The structure of the bridge 130C can be achieved via various processes. However, in some examples, the bridge 130C can be formed via a process similar to the process of FIGS. 2A-2F, but with the wafer providing process of FIG. 2A modified. For example, the bridge wafer 131 can simply be received at FIG. 2A with one or more bridge integrated circuit devices 136 already present in the bridge dies 132. Alternatively, prior to the formation of the bridge signal distribution structure 135, the wafer providing process of FIG. 2A can include various front end processes that form one or more bridge integrated circuit devices 136 into a front side of the bridge die 132.

FIG. 3C depicts the bridge 130C with the lower ends of the bridge through-interconnects 133 covered by the bridge mold layer 134 similar to the bridge 130B of FIG. 3B. However, in some examples, the bridge mold layer 134 of the bridge 130C can leave the lower ends of the bridge through-interconnects 133 exposed similar to the bridge 130A of FIG. 3A.

FIG. 3D depicts a bridge 130D with a bridge lower signal distribution structure 135B. The bridge 130D of FIG. 3D, like the bridge 130A of FIG. 3A, can include a bridge die 132, bridge through-interconnects 133, a bridge mold layer 134, a bridge signal distribution structure 135, a bridge die attach film 137, bridge upper interconnects 138, and bridge lower interconnects 139. However, the bridge 130D can further include a bridge lower signal distribution structure 135B.

The structure of the bridge 130D can be achieved via various processes. However, in some examples, the bridge 130D can be formed via a process similar to the process of FIGS. 2A-2F, but with the formation of the bridge lower signal distribution structure 135B between the processes of FIGS. 2D and 2E. Such formation of the bridge lower signal distribution structure 135B can mechanically and electrically couple a signal distribution conductive structure of the bridge lower signal distribution structure 135B to lower ends of the bridge through-interconnects 133. Moreover, the bridge lower signal distribution structure 135B can have corresponding elements, features, materials, or manufacturing methods similar to those of the bridge signal distribution structure 135 and/or any other substrate or signal distribution structure described herein.

FIG. 3D depicts the bridge 130D with the lower ends of the bridge through-interconnects 133 covered by the bridge mold layer 134. However, in some examples, the bridge mold layer 134 of the bridge 130D can leave the lower ends of the bridge through-interconnects 133 covered similar to the bridge 130A of FIG. 3A.

FIG. 3D depicts the bridge 130D without integrated circuit devices. However, in various examples, the bridge die 132 of the bridge 130D can include bridge integrated circuit devices in its top side and/or bottom side in a manner similar to the bridge integrated circuit device 136 of the bridge 130C shown in FIG. 3C. Furthermore, while bridges 130A, 130B, 130C are depicted with a single bridge signal distribution structure 135, in various examples, each bridge 130A, 130B, 130C can include a bridge lower signal distribution structure similar to the bridge lower signal distribution structure 135B of bridge 130D.

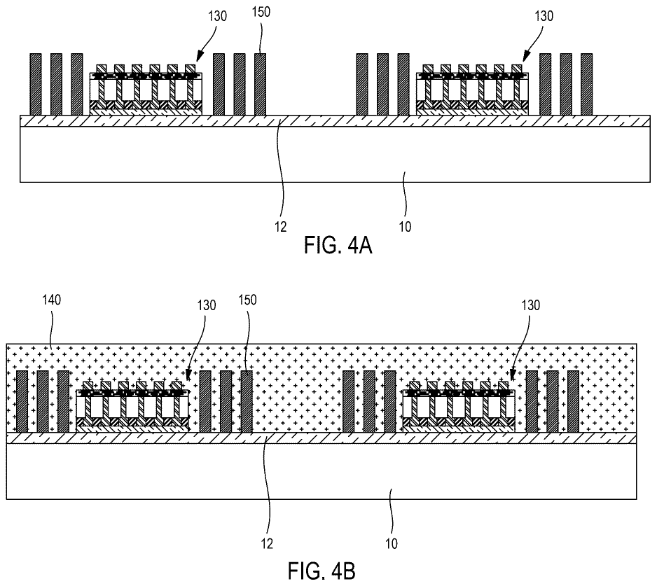

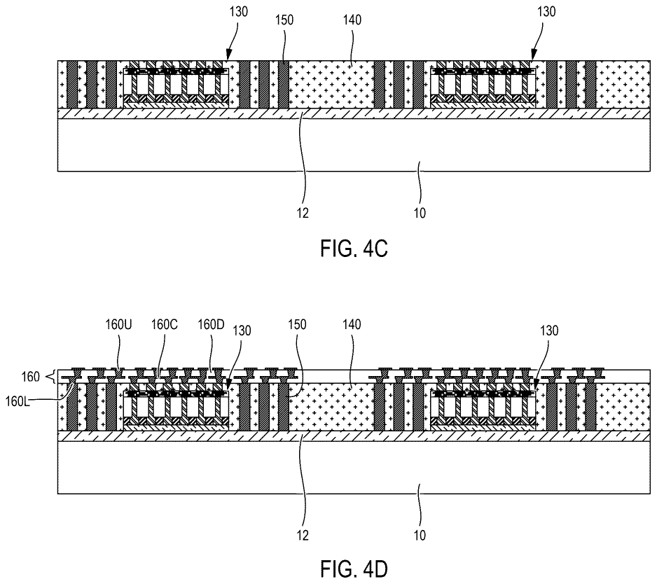

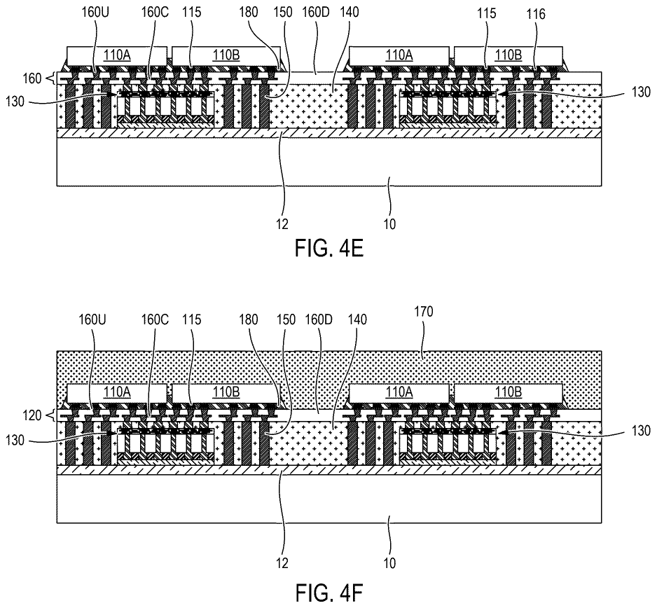

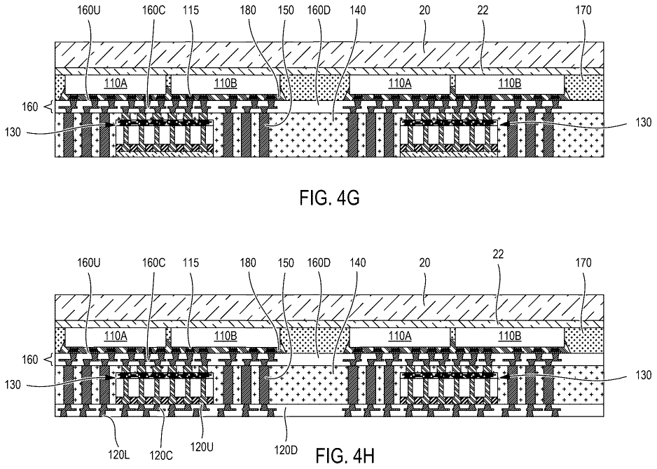

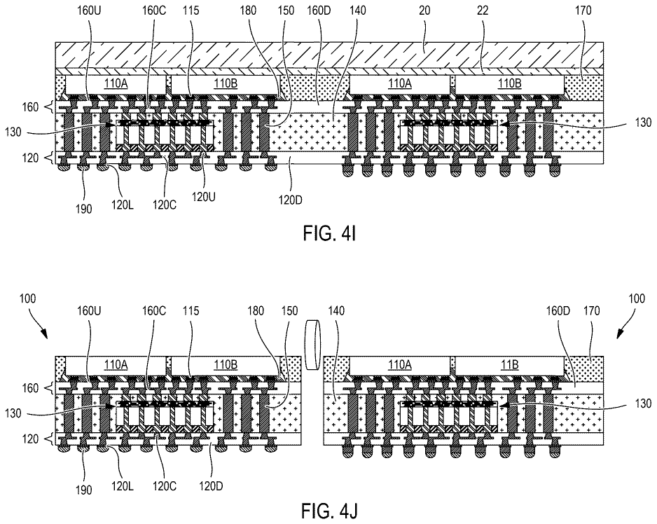

FIGS. 4A to 4J show cross-sectional views of an example method for manufacturing the electronic device 100 of FIG. 1. FIG. 4A shows a cross-sectional view of the electronic device 100 at an early stage of manufacture. In the example shown in FIG. 4A, multiple bridges 130 and multiple internal interconnects 150 can be provided on a top side of a first carrier 10. In particular, the first carrier 10 can include a temporary bond layer 12, which can be in contact with lower ends of the interconnects 150 and a bottom side of the bridge die attach film 137 for each bridge 130

In accordance with various examples, the internal interconnects 150 can be made of a conductive material such as, for example, copper, gold, silver, palladium, or nickel. The internal interconnects 150 can be provided by electrolytic plating, electroless plating, sputtering, physical vapor deposition (PVD), chemical vapor deposition (CVD), metal organic chemical vapor deposition (MOCVD), atomic layer deposition (ALD), low pressure chemical vapor deposition (LPCVD), or plasma enhanced chemical vapor deposition (PECVD), or ball drop. In some examples, a seed layer can be formed over temporary bond layer 12 on the top side of the first carrier 10, and then a mask pattern can be provided on a top side of the seed layer. The internal interconnects 150 can be formed by plating over exposed portions of the seed layer. After the internal interconnects 150 are provided, the mask pattern(s) can be removed.

The internal interconnects 150 can be provided in rows and/or columns over the first carrier 10. In some examples, the height (i.e., thickness) of the internal interconnects 150 can range from approximately 800 μm to approximately 2000 μm. The internal interconnects 150 can include or be referred to as vertical conductive structures such as pillars, posts, through mold vias (TMVs), copper core solder balls (CCBs), or solder balls, or copper cube columns (CCCs). In accordance with various examples, CCCs can include a plurality of vertical conductive structures (e.g., columns, pillars, posts, etc.) disposed in an insulating body, such as mold material (e.g., an epoxy mold compound, resin, organic polymer with inorganic filler, etc.).

The first carrier 10 can include a substantially planar top side. In some examples, the first carrier 10 can include or be referred to as a plate, a board, a wafer, a panel, or a strip. For example, the first carrier 10 can be provided as a wafer. In some examples, the thickness of the first carrier 10 can range from approximately 50 μm to approximately 800 μm, and the width of the first carrier 10 can range from approximately 100 millimeters to approximately 650 mm. The first carrier 10 can serve to integrally handle multiple components in the process of providing the lower substrate 120, the bridges 130, the lower encapsulant 140, and the internal interconnects 150.

In the example shown in FIG. 4A, the bridges 130 can be provided on the temporary bond layer 12 over the top side of first carrier 10. Each bridge 130 can be coupled to or otherwise adhered to the top side of the first carrier 10 via its bridge die attach film 137 along its bottom side.

In various examples, each bridge 130 can any of the bridges 130A, 130B, 130C, 130D shown in FIGS. 3A-3D and/or any of the variations described with respect to FIGS. 3A-3D. In some examples, all bridges 130 can be similar. In other examples, the bridges 130 can be a mix of the bridges described with respect to FIGS. 3A-3D.

In some examples, the bridges 130 can be picked up by pick-and-place equipment and placed on the top side of the first carrier 10. More specifically, the bridges 130 can be placed such that their respective bridge die attach films 137 affix the bridges 130 to the first carrier 10. In some examples, the overall thickness of bridge 130 can range from approximately 10 μm to approximately 800 μm, and the area of bridge 130 can range from approximately 0.5 mm×0.5 mm to approximately 100 mm×100 mm.

Referring now to FIG. 4B, a cross-sectional view of the electronic device 100 at a later stage of manufacture is shown. In the example shown in FIG. 4B, the lower encapsulant 140 can be provided to cover the first carrier 10, the bridges 130, and the internal interconnects 150. The lower encapsulant 140 can be in contact with the temporary bond layer 12 on the top side of the first carrier 10, the lateral sides or sidewalls of the bridges 130, the top side of the bridges 130, the lateral sides or sidewalls of the internal interconnects 150, and the upper ends of the internal interconnects 150. In some examples, the lower encapsulant 140 can be provided by compression molding, transfer molding, liquid body molding, vacuum lamination, paste printing, or film-assisted molding an epoxy mold compound, resin, and/or organic polymer that comprises an inorganic filler, a curing agent, a catalyst, a coupling agent, a colorant, and/or a flame retardant.

After the lower encapsulant 140 is provided to cover the top side and sidewalls of the bridges 130, and the top side and sidewalls of each internal interconnect 150, the upper portion of the lower encapsulant 140 can be removed to expose the upper ends of each bridge upper interconnect 138 and the upper ends of each internal interconnect 150 as shown at FIG. 4C. For example, the upper portion of the lower encapsulant 140 can be removed by a general grinding and/or chemical etching of the top side of the lower encapsulant 140. The thickness of the lower encapsulant 140 can range from approximately 20 μm to approximately 800 μm. The lower encapsulant 140 can protect the bridges 130 and the internal interconnects 150 from external elements.

FIG. 4D shows a cross-sectional view of the electronic device 100 at a later stage of manufacture. In the example shown in FIG. 4D, the upper substrate 160 can be provided such that the upper substrate 160 can be positioned over, can cover, and/or can be coupled to the lower encapsulant 140, the bridge 130, and the internal interconnects 150.

The upper substrate 160 can include an upper substrate dielectric structure 160D and an upper substrate conductive structure 160C. The upper substrate conductive structure 160C can include upper substrate upper terminals 160U and upper substrate lower terminals 160L. In particular, providing the upper substrate dielectric structure 160D can spin coating, spray coating, dip coating, rod coating, PVD, CVD, or any other suitable methods for forming an electrically insulating material such as polyimide (PI), benzocyclobutene (BCB), polybenzoxazole (PBO), resin, or Ajinomoto buildup film (ABF). Such formation can provide the upper substrate dielectric structure 160D such that upper substrate dielectric structure 160D is over, cover, and/or is coupled to a top side of the lower encapsulant 140, an upper end of each bridge upper interconnect 138, and an upper end of each internal interconnects 150. In some examples, after the lowermost (or first) layer of the upper substrate dielectric structure 160D is provided, openings exposing an upper end of each bridge upper interconnect 138 and an upper end of each internal interconnect 150 can be provided. For example, after forming a mask pattern on the top side of the lowermost layer of the upper substrate dielectric structure 160D, openings can be formed by removing exposed portions of the dielectric layer through etching. Portions of upper substrate conductive structure 160C can then be provided in the openings, such that the portions of upper substrate conductive structure 160C can couple to and/or can contact exposed upper ends of the bridge upper interconnects 138 and exposed upper ends of the internal interconnects 150.

Formation of the bridge signal distribution structure 135 can interleave the upper substrate conductive structure 160C with the upper substrate dielectric structure 160D such that. the upper substrate conductive structure 160C contacts and/or is electrically coupled to upper ends of the internal interconnects 150 and to upper ends of the bridge upper interconnects 138. In particular, the upper substrate conductive structure 160C can be provided by electrolytic plating, electroless plating, sputtering, PVD, CVD, MOCVD, ALD, LPCVD, PECVD, or any other suitably process for deposing metals such as copper, gold, silver, aluminum, nickel, palladium, titanium, tungsten, etc. In some examples, the upper substrate conductive structure 160C can be provided by plating. For example, after a metal seed layer is provided to cover exposed upper ends of the bridge upper interconnects 138, exposed upper ends of the internal interconnects 150, and a top side of a dielectric layer of the upper substrate dielectric structure 160D, a mask pattern can be provided to cover the top side of the metal seed layer. A conductive layer of the upper substrate conductive structure 160C can then be provided through plating using exposed portions of the metal seed layer as a seed. For example, a photoresist can be used as the mask pattern. After the conductive layer is formed, the mask pattern can be removed.

The conductive patterns can be formed using a plating process such as, for example, an electroplating process or an electroless plating process. The conductive patterns can include a conductive material such as, for example, copper or other plateable metal. The locations of the conductive patterns can be made using a photo-patterning process such as, for example, a photolithography process and a photoresist material to form a photolithographic mask. The dielectric layers of the RDL substrate can be patterned with a photo-patterning process, and can include a photolithographic mask through which light is exposed to photo-pattern desired features such as vias in the dielectric layers.

The dielectric layers can be made from photo-definable organic dielectric materials such as, for example, polyimide (PI), benzocyclobutene (BCB), or polybenzoxazole (PBO). Such dielectric materials can be spun-on or otherwise coated in liquid form, rather than attached as a pre-formed film. To permit proper formation of desired photo-defined features, such photo-definable dielectric materials can omit structural reinforcers or can be filler-free, without strands, weaves, or other particles that can interfere with light from the photo-patterning process. In some examples, such filler-free characteristics of filler-free dielectric materials can permit a reduction of the thickness of the resulting dielectric layer. Although the photo-definable dielectric materials described above can be organic materials, in some examples the dielectric materials of the RDL substrate can include one or more inorganic dielectric layers. Some examples of inorganic dielectric layer(s) can include silicon nitride (Si3N4), silicon oxide (SiO2), and/or silicon oxynitride (SiON). The inorganic dielectric layer(s) can be formed by growing the inorganic dielectric layers using an oxidation or nitridization process instead of using photo-defined organic dielectric materials. Such inorganic dielectric layers can be filler-fee, without strands, weaves, or other dissimilar inorganic particles. In some examples, RDL substrates can omit a permanent core structure or carrier such as, for example, a dielectric material comprising bismaleimide triazine (BT) or FR4 and these types of RDL substrates can include or be referred to as a coreless substrate. Other substrates and signal distribution structures of this disclosure such as the bridge signal distribution structures 135, 135B and/or the lower substrate 120 can include RDL substrates.

In some examples, the upper substrate 160 can include a pre-formed or laminate substrate. The pre-formed substrate can be manufactured prior to attachment to an electronic component and can include dielectric layers between respective conductive layers. The conductive layers can include copper and can be formed using an electroplating process. The dielectric layers can be relatively thicker non-photo-definable layers and can be attached as a pre-formed film rather than as a liquid and can include a resin with fillers such as strands, weaves, and/or other inorganic particles for rigidity and/or structural support. Since the dielectric layers are non-photo-definable, features such as vias or openings can be formed by using a drill or laser. In some examples, the dielectric layers can include a prepreg material or Ajinomoto Buildup Film (ABF). The pre-formed substrate can include a permanent core structure or carrier such as, for example, a dielectric material comprising bismaleimide triazine (BT) or FR4, and dielectric and conductive layers can be formed on the permanent core structure. In other examples, the pre-formed substrate can be a coreless substrate and omits the permanent core structure, and the dielectric and conductive layers can be formed on a sacrificial carrier that is removed after formation of the dielectric and conductive layers and before attachment to the electronic component. The pre-formed substrate can be referred to as a printed circuit board (PCB) or a laminate substrate. Such pre-formed substrates can be formed through a semi-additive or modified-semi-additive process. Other substrates and signal distribution structures of this disclosure such as the bridge signal distribution structures 135, 135B and/or the lower substrate 120 can include a pre-formed substrate.

FIG. 4E shows a cross-sectional view of the electronic device 100 at a later stage of manufacture. In the example shown in FIG. 4E, first electronic components 110A and second electronic components 110B can be provided on the top side of the upper substrate 160. Each of the first electronic components 110A and the second electronic components 110B can include electronic component interconnects 115.

Pick-and-place equipment can pick up the first electronic components 110A and the second electronic components and place the first electronic components 110A and the second electronic components 110B on the top side of the upper substrate 160. The electronic component first interconnects 115 and the electronic component second interconnects 116 of each electronic component 110A, 110B can be positioned on a top side of a respective upper substrate upper terminal 160U. Subsequently, the electronic component first interconnects 115 and the electronic component second interconnect 116 can be bonded with their respective upper substrate upper terminals 160U through a reflow process, a thermal compression process, or a hybrid bonding process.

As further shown in the example of FIG. 4E, the underfill 180 can be provided between the upper substrate 160 and the first electronic components 110A. Further, the underfill 180 can be provided between the upper substrate 160 and the second electronic components 110B. In some examples, the underfill 180 can span the lateral space between the first electronic component 110A and its respective second electronic component 110B. In some examples, the underfill process of FIG. 4E can be omitted. In such examples, the formation of the upper encapsulant 170 of FIG. 4F can underfill the first electronic components 110A and the second electronic components 110B effectively replacing the underfill 180. In such examples, the upper encapsulant 170 can provide as molded underfill (MUF).

FIG. 4F shows a cross-sectional view of the electronic device 100 at a later stage of manufacture. In the example shown in FIG. 4F, the upper encapsulant 170 can be provided to cover the first electronic components 110A, the second electronic components 110B, and/or the underfill 180. The upper encapsulant 170 can contact a top side and sidewalls of each first electronic component 110A, a top side and sidewalls of each second electronic components 110B, a top side of the upper substrate 160, and/or a sidewall of the underfill 180. In some examples, the upper encapsulant 170 can expose a top side of each first electronic component 110A and/or a top side of each second electronic component 110B. For example, the top side of the upper encapsulant 170 can be coplanar with the top side of each first electronic component 110A and can be coplanar with the top side of each second electronic components 110B.

In some examples, the upper encapsulant 170 can be in contact with sidewalls of the upper substrate 160 and/or sidewalls of the lower encapsulant 140. The upper encapsulant 170 can have corresponding elements, features, materials, or manufacturing methods similar to those of the lower encapsulant 140 and/or any other encapsulant described herein.

FIG. 4G shows a cross-sectional view of the electronic device 100 at later stages of manufacture. In the example shown in FIG. 4G, a second carrier 20 can be provided over the top side of each first electronic component 110A, over the top side of each second electronic components 110B, and over the top side of the upper encapsulant 170. Further, the first carrier 10 can be removed from the bottom side of each bridge die attach film 137 for the bridges 130, from the bottom side of the lower encapsulant 140, and from the lower ends of the internal interconnects 150.

The second carrier 20 can include a temporary bond layer 22, which can be in contact with the top side of each first electronic component 110A, with the top side of each second electronic components 110B, and with the top side of the upper encapsulant 170. The second carrier 20 can have elements, features, materials, or manufacturing methods similar to or the same as those of the first carrier 10 and/or any other carrier described herein.

As a result of the first carrier 10 being removed, the bottom side of lower encapsulant 140, the lower ends of the internal interconnects 150, the bottom side of each bridge die attach film 137 can be exposed. In some examples, the removal of the first carrier 10 can pull, can strip, and/or can otherwise remove all or portions of each bridge die attach film 137 from its respective bridge 130. In such examples, the bottom side of the bridge mold layer 134 can be exposed after removal of the first carrier 10. Further, some and/or all of the lower ends of the bridge through-interconnects 133 can be exposed after removal of the first carrier 10.

FIG. 4H shows a cross-sectional view of the electronic device 100 at later stages of manufacture. In the example shown in FIG. 4H, a lower portion of each bridge 130, a lower portion of the lower encapsulant 140, and a lower portion of each internal interconnects 150 can be removed to expose lower ends of the bridge lower interconnects 139 of each bridge 130. In particular, such lower portions can be removed by a general grinding and/or chemical etching of exposed lower portions. Such removal of the lower portion of each bridge 130 can remove portions of the bridge mold layer 134, the bridge die attach film 137, and the bridge lower interconnects 139 until at least each lower end of the bridge lower interconnects 139 is exposed. Further, such removal can also remove lower portions of the lower encapsulant 140 and lower portions of the internal interconnects 150. In some examples, the lower ends of each bridge lower interconnects 139 can be coplanar with a bottom side of the bridge mold layer 134 after such grinding and/or chemical etching. Further, the bridge mold layer 134 can be coplanar with the bottom side of the lower encapsulant and can be coplanar with the lower ends of the internal interconnects 150.

The process of exposing the lower ends of the bridge lower interconnects 139 can negatively affect operation of the resulting device. Namely, grinding and/or etching of the lower ends of the bridge lower interconnects 139 can create metal ions (e.g., copper ions) due to the removal of metal from the bridge lower interconnects 139 and/or metal from the internal interconnects 150. The bridge mold layer 134 can provide a protective layer that covers the bottom side of the bridge die 132 and inhibits such metal ions from migrating into the bridge die 132. As such, the bridge mold layer 134 can help prevent negative effects associated with such ion migration.

As further shown at FIG. 4H, a lower substrate 120 can be provided that can cover and/or can couple to the lower end of each bridge lower interconnect 139, the bottom side of the lower encapsulant 140, and the lower end of each internal interconnect 150. In particular, the lower substrate 120 can be provided with a lower substrate dielectric structure 120D and the lower substrate conductive structure 120C. Further, the lower substrate conductive structure 120C can provided to include lower substrate upper terminals 120U and the lower substrate lower terminals 120L. To this end, the lower substrate 120 can be provided in a manner similar to the upper substrate 160. In particular, the lower substrate 120 can have corresponding elements, features, materials, or manufacturing methods similar to those of the upper substrate 160 and/or any other substrate or signal distribution structure described herein.

FIG. 4I shows a cross-sectional view of the electronic device 100 at a later stage of manufacture. In the example shown in FIG. 4I, lower substrate interconnects 190 can be provided on bottom side of the lower substrate 120. In particular, the lower substrate interconnects 190 can be provided such that the lower substrate interconnects 190 are coupled to and in contact with the lower substrate lower terminals 120L of the lower substrate conductive structure 120C. In some examples, the lower substrate interconnects 190 can include tin (NS), silver (Ag), lead (Pb), copper (Cu), Sn—Pb, Sn37—Pb, Sn95—Pb, Sn—Pb—Ag, Sn—Cu, Sn—Ag, Sn—Au, Sn—Bi, or Sn—Ag—Cu. For example, the lower substrate interconnects 190 can be provided through a reflow process after forming a conductive material including solder on lower substrate lower terminals 120L through a ball drop method. The lower substrate interconnects 190 can include or be referred to as conductive balls such as solder balls, conductive pillars such as copper pillars, or conductive posts having solder caps provided on copper pillars. In some examples, the sizes of each lower substrate interconnect 190 can range from approximately 0.5 μm to approximately 1000 μm.

After the lower substrate interconnects 190 are provided, the electronic device 100 can be subjected to a singulation process as shown in FIG. 4J. In particular, the upper encapsulant 170, the upper substrate 160, the lower encapsulant 140, and the lower substrate 120 can be sawed along streets S to separate into individual electronic devices 100. In some examples, the singulation process can be performed by using either a diamond blade or a laser beam. The second carrier 20 attached to the top side of individual electronic devices 100 can also be removed. In some examples, the lower substrate interconnects 190 can be referred to as external input/output terminals of individual electronic devices 100.

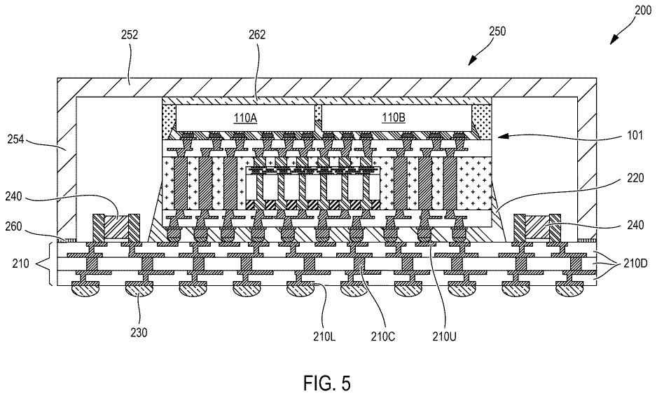

Turning now to FIG. 5, a cross-sectional view of an electronic device 200 is shown. In accordance with various examples, the electronic device 200 can include one or more electronic modules 101, a device substrate 210, an underfill 220, and external interconnects 230. In some examples, the electronic device 200 can further include one or more electronic components 240 and a stiffener 250.

The device substrate 210 can include a device substrate dielectric structure 210D and a device substrate conductive structure 210C. In some examples, the device substrate dielectric structure 210D can include or be referred to as one or more stacked dielectric layers. For instance, the one or more dielectric layers can include, one or more core layers, polymer layers, pre-preg layers, or solder mask layers stacked on each other. One or more layers or elements of the device substrate conductive structure 210C can be interleaved with one or more layers or elements of the device substrate dielectric structure 210D. In some examples, the device substrate dielectric structure 210D can include or be referred to as polyimide (PI), benzocyclobutene (BCB), polybenzoxazole (PBO), resin, Ajinomoto Buildup Film (ABF), epoxy or ceramic. In some examples, the thickness of device substrate dielectric structure 210D can range from approximately 10 μm to 1000 μm.

The device substrate conductive structure 210C can include one or more conductive layers that define conductive paths with elements such as traces, pads, vias, and wiring patterns. The device substrate conductive structure 210C can include device substrate upper terminals 210U provided on a top side of the device substrate 210, device substrate lower terminals 210L provided on a bottom side of the device substrate 210. Lower substrate interconnects 190 of each electronic module 101 can be in contact with and/or can be electrically coupled to device substrate upper terminals 210U of the device substrate 210.

The device substrate upper terminals 210U can be provided at a top side of the device substrate 210 and the device substrate lower terminals 210L can be provided at a bottom side of device substrate 210. The device substrate upper terminals 210U and/or the device substrate lower terminals 210L can be arranged in a respective matrix having rows and/or columns. In some examples, the device substrate upper terminals 210U and the device substrate lower terminals 210L can include or be referred to as a conductor, a conductive material, a substrate land, a conductive land, a substrate pad, a wiring pad, a connection pad, a micro pad, or under-bump-metallurgy (UBM).

The device substrate conductive structure 210C can be provided in the device substrate dielectric structure 210D to couple the device substrate upper terminals 210U with the device substrate lower terminals 210L. In some examples, the device substrate conductive structure 210C can include copper, iron, nickel, gold, silver, palladium, or tin.

In some examples, the device substrate 210 can include or be referred to as a laminate substrate, a ceramic substrate, a rigid substrate, a glass substrate, a silicon substrate, a printed circuit board, a multilayer substrate, or a molded lead frame. In some examples, the device substrate 210 can include or be referred to as an RDL substrate, a buildup substrate, or a coreless substrate. In some examples, the device substrate 210 can have an area varying according to the quantity of electronic modules 101 and/or an accumulative area consumed by the one or more electronic modules 101. In some examples, the device substrate 210 can have an area of approximately 8 mm×8 mm to approximately 500 mm×500 mm. The device substrate 210 can also have a thickness of approximately 0.5 mm to approximately 4 mm.

The device substrate 210 can be electrically coupled to the electronic components 110A, 110B of each electronic module 101 through the lower substrate interconnects 190, the lower substrate 120, the internal interconnects 150, and the upper substrate 160 of the respective electronic module 101. The device substrate 210 can be further electrically coupled to the electronic components 110A, 110B of each electronic module 101 through the lower substrate interconnects 190, the lower substrate 120, the bridge 130, and the upper substrate 160 of the respective electronic module 101.

In various examples, each electronic module 101 comprises an electronic device 100 of FIG. 1. Further, each electronic module 101 can be coupled to the device substrate 210. For example, lower substrate interconnects 190 of each electronic module 101 can be coupled to and/or can contact the device substrate upper terminals 210U. More specifically, each electronic module 101 can be seated on the device substrate 210 and an underfill 220 can be provided between each electronic module 101 and the device substrate 210. While each electronic module 101 is depicted with a bridge 130, each electronic module 101 can include any of the bridges 130A, 130B, 130C, 130D of FIGS. 3A to 3D and/or any of the bridge variations otherwise presented herein.

As shown, one or more electronic components 240 can be coupled to a top side of the device substrate 210. Each electronic component 240 can include or be referred to as a die, a chip, a package (e.g., an encapsulated device including one or more semiconductor die), an active device, or a passive device.

The underfill 220 can be provided between the top side of the device substrate 210 and a bottom side of each electronic module 101. The underfill 220 can contact and/or can be coupled to the top side of the device substrate 210, sidewalls of the lower substrate interconnects 190, and the bottom side of the lower substrate 120. In some examples, the underfill 220 can help prevent the one or more electronic modules 101 from being separated from the device substrate 210 due to physical impacts and/or thermal impacts. In various examples, the underfill 220 can be provided between the top side of the device substrate 210 and a bottom side of each electronic component 240. In such examples, the underfill 220 can further help prevent the one or more electronic components 240 from being separated from the device substrate 210 due to physical impacts and/or thermal impacts. The underfill 220 can have corresponding elements, features, materials, and/or manufacturing methods similar to those of the underfill 180 and/or any other underfill disclosed herein.

As shown, the electronic device 200 can further include the stiffener 250. The stiffener 250 can be provided on the device substrate 210. The stiffener 250 can be attached to the top side of the device substrate 210 and/or can surround the one or more electronic modules 101. The stiffener 250 can include four square side walls coupled to each other. The stiffener 250 can have four square side walls spaced apart from the sidewalls of the one or more electronic modules 101. The stiffener 250 can have a square or rectangular ring shape in a plan (top down) view. A bottom side of each sidewall of stiffener 250 can be coupled to the top side of the device substrate 210 through an adhesive layer. Stiffener 250 can help reduce or prevent warpage of the device substrate 210. In some examples, stiffener 250 can include stainless steel, polymer, silicon, metal, glass, or ceramic.

In some examples, the stiffener 250 can be referred to or take the form of a lid, a heat sink, a heat dissipation plate, a cap cover, an encapsulation portion, a protective portion, a package, or a body. In some examples, the stiffener 250 can provide electromagnetic interference (EMI) shielding. In particular, FIG. 5 depicts the stiffener 250 in the form of a lid that comprises a lid cover member 252 and lid sidewalls 254. The lid cover member 252 can cover the top side of the first electronic component 110A and the top side of second electronic components 110B. In various examples, the lid cover member 252 and/or lid sidewalls 254 can be made of metal with high heat conduction. In some examples, the lid cover member 252 and/or lid sidewalls 254 can include aluminum or copper.

The lid sidewalls 254 can cover the sidewalls or lateral sides of the one or more electronic modules 101. Further, the lid sidewall 254 can be coupled to the top side of the device substrate 210 via a first attachment material 260. In some examples, the lid cover member 252 and/or lid sidewalls 254 can be electrically coupled to the device substrate conductive structure 210C. In particular, the first attachment material 260 can be include solder, conductive adhesive, and/or some other conductive material which mechanically and electrically couples bottom sides of the lid sidewalls 254 to the device substrate conductive structure 210C.

In some examples, a second attachment material 262 can be interposed between a bottom side of the lid cover member 252 and a top side of the first electronic component 110A and/or a top side of the second electronic component 110B to facilitate heat transfer and coupling. The second attachment material 262 can include or be referred to as an adhesive, a thermal interface material (TIM) layer, or solder. In some examples, the second attachment material 262 can include a back side metal (BSM) located on the top side of the first electronic component 110A and/or the top side of the second electronic component 110B.

The electronic device 200 can also include external interconnects 230. The external interconnects 230 can be provided along the bottom side of the device substrate 210. The external interconnects 230 can be in contact with and/or can be electrically coupled to the device substrate lower terminals 210L. The external interconnects 230 can be ball-grid arrayed or land-grid-arrayed along the device substrate bottom side. In some examples, the size of each external interconnect 230 can range from approximately 10 μm to approximately 800 μm. In some examples, the external interconnects 230 can be referred to as external input/output terminals of the electronic device 200. The external interconnects 230 can have elements, features, materials, and/or manufacturing methods similar to or the same as those of lower substrate interconnects 190 and/or any other external interconnects disclosed herein.

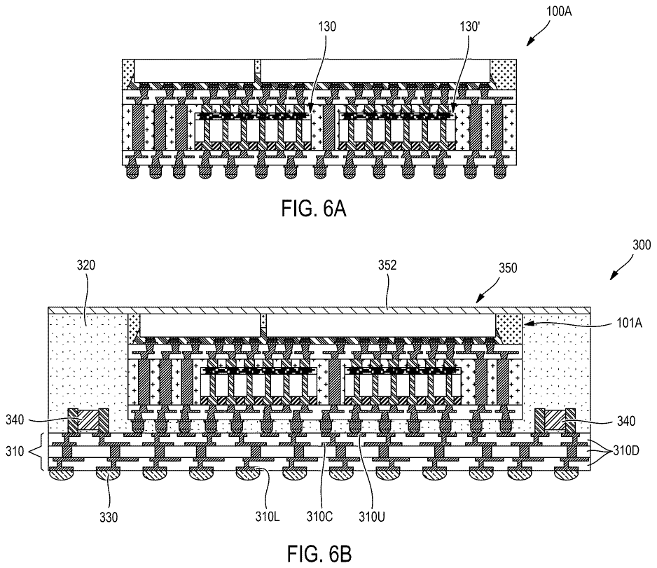

FIG. 6A shows a cross-sectional view of an example the electronic device 100A. The electronic device 100A can be implemented in a manner similar to the electronic device 100 of FIG. 1. Namely, similar to the electronic device 100, the electronic device 100A can include one or more electronic components 110A, 110B, a lower substrate 120, one or more first bridges 130, a lower encapsulant 140, one or more internal interconnects 150, an upper substrate 160, an upper encapsulant 170, an underfill 180, and lower substrate interconnects 190. Each of such aspects of the electronic device 100A can have elements, features, materials, and/or manufacturing methods similar to or the same as corresponding aspects of electronic device 100 and/or any other electronic device disclosed herein.

The electronic device 100A can further include one or more second bridges 130′. Each second bridge 130′ can have elements, features, materials, and/or manufacturing methods similar to or the same as corresponding aspects of the bridge 130. In particular, each second bridge 130′ can include any of the bridges 130A, 130B, 130C, 130D of FIGS. 3A to 3D and/or any of the bridge variations discussed herein.

As explained above, each first bridge 130, among other things, can provide conductive paths that electrically couple the first electronic component 110A and the second electronic component 110B together. In this manner, signals can be passed between the first electronic component 110A and the second electronic component 110B through the one or more first bridges 130 without passing through the lower substrate 120. However, as shown, each second bridge 130′ can be positioned below and coupled to a single electronic component (e.g., the second electronic component 110B) via the upper substrate 160. As such, each second bridge 130′ can provide further routing (e.g., power, ground, data signals) between the lower substrate 120 and the single electronic component to which it is coupled via the upper substrate 160. But, unlike the one or more first bridges 130, each second bridge 130′ can provide no additional signal routing between first electronic component 110A and the second electronic component 110B.

Turning now to FIG. 6B, a cross-sectional view of an electronic device 300 is shown. In accordance with various examples, the electronic device 300 can include one or more electronic modules 101A, a device substrate 310, an encapsulant 320, and external interconnects 330. In some examples, the electronic device 300 can further include one or more electronic components 340 and a stiffener 350.

The device substrate 310 can include a device substrate dielectric structure 310D and a device substrate conductive structure 310C. In some examples, the device substrate dielectric structure 310D can include or be referred to as one or more stacked dielectric layers. For instance, the one or more dielectric layers can include one or more core layers, polymer layers, pre-preg layers, or solder mask layers stacked on each other. One or more layers or elements of the device substrate conductive structure 310C can be interleaved with one or more layers or elements of the device substrate dielectric structure 310D. In some examples, the device substrate dielectric structure 310D can include or be referred to as polyimide (PI), benzocyclobutene (BCB), polybenzoxazole (PBO), resin, Ajinomoto Buildup Film (ABF), epoxy or ceramic. In some examples, the thickness of device substrate dielectric structure 310D can range from approximately 10 μm to 1000 μm.

The device substrate conductive structure 310C can include one or more conductive layers that define conductive paths with elements such as traces, pads, vias, and wiring patterns. The device substrate conductive structure 310C can include device substrate upper terminals 310U provided on a top side of the device substrate 310, device substrate lower terminals 310L provided on a bottom side of the device substrate 310. Lower substrate interconnects 190 of each electronic module 101A can be in contact with and/or can be electrically coupled to device substrate upper terminals 310U of the device substrate 310.

The device substrate upper terminals 310U can be provided at a top side of the device substrate 310 and the device substrate lower terminals 310L can be provided at a bottom side of device substrate 310. The device substrate upper terminals 310U and/or the device substrate lower terminals 310L can be arranged in a respective matrix having rows and/or columns. In some examples, the device substrate upper terminals 310U and the device substrate lower terminals 310L can include or be referred to as a conductor, a conductive material, a substrate land, a conductive land, a substrate pad, a wiring pad, a connection pad, a micro pad, or under-bump-metallurgy (UBM).

The device substrate conductive structure 310C can be provided in the device substrate dielectric structure 310D to couple the device substrate upper terminals 310U with the device substrate lower terminals 310L. In some examples, the device substrate conductive structure 310C can include copper, iron, nickel, gold, silver, palladium, or tin.

In some examples, the device substrate 310 can include or be referred to as a laminate substrate, a ceramic substrate, a rigid substrate, a glass substrate, a silicon substrate, a printed circuit board, a multilayer substrate, or a molded lead frame. In some examples, the device substrate 310 can include or be referred to as an RDL substrate, a buildup substrate, or a coreless substrate. In some examples, the device substrate 310 can have an area varying according to the quantity of electronic modules 101A and/or an accumulative area consumed by the one or more electronic modules 101A. In some examples, the device substrate 310 can have an area of approximately 8 mm×8 mm to approximately 500 mm×500 mm. The device substrate 310 can also have a thickness of approximately 0.5 mm to approximately 4 mm.

The device substrate 310 can be electrically coupled to the electronic components 110A, 110B of each electronic module 101A through the lower substrate interconnects 190, the lower substrate 120, the internal interconnects 150, and the upper substrate 160 of the respective electronic module 101A. The device substrate 310 can be further electrically coupled to the electronic components 110A, 110B of each electronic module 101A through the lower substrate interconnects 190, the lower substrate 120, the one or more first bridges 130, and the upper substrate 160 of the respective electronic module 101A. The device substrate 310 can be further electrically coupled to the second electronic component 110B of each electronic module 101A through the lower substrate interconnects 190, the lower substrate 120, the one or more second bridges 130′, and the upper substrate 160 of the respective electronic module 101A.

In various examples, each electronic module 101A can comprise an electronic device 100A of FIG. 6A. Further, each electronic module 101A can be coupled to the device substrate 310. For example, lower substrate interconnects 190 of each electronic module 101A can be coupled to and/or can contact the device substrate upper terminals 310U. More specifically, each electronic module 101A can be seated on the device substrate 310.

As shown, one or more electronic components 340 can be coupled to a top side of the device substrate 310. Each electronic component 340 can include or be referred to as a die, a chip, a package (e.g., an encapsulated device including one or more semiconductor die), an active device, or a passive device.

The encapsulant 320 can protect the one or more electronic modules 101A and the one or more electronic components 340 coupled to the top side of the device substrate 310. In some examples, the encapsulant 320 can cover, can contact, and/or surround each electronic module 101A and can cover, can contact, and/or surround each electronic component 340. In particular, in some examples, the encapsulant 320 can contact and/or laterally surround lateral sides of each electronic module 101A, can cover and/or contact a top side of device substrate 310, and can cover, contact, and/or laterally surround a top side and/or lateral sides of each electronic component 340. In some examples, the encapsulant 320 can expose a top side of each electronic component 110A, 110B of the electronic modules 101A. In such examples, the top side of the encapsulant 320 can be coplanar with the top side of each electronic component 110A, 110B. To this end, the encapsulant 320 can have corresponding elements, features, materials, or manufacturing methods similar to those of the lower encapsulant 140, the upper encapsulant 170, and/or any other encapsulant disclosed herein.

As shown, the electronic device 300 can further include the stiffener 350. The stiffener 350 can be provided over and/or coupled to the top side of each electronic component 110A, 110B and to the top side of the encapsulant 320. Similar to the stiffener 250 of FIG. 5, the stiffener 350 can be referred to or take the form of a heat sink, a heat dissipation plate, a cap cover, an encapsulation portion, a protective portion, a package, or a body. Further, in some examples, the stiffener 350 can provide electromagnetic interference (EMI) shielding. In particular, FIG. 6B depicts the stiffener 350 in the form of a metal layer 352 deposited on the top side or back side of each electronic component 110A, 110B. The metal layer 352 can be provided to cover the top side of each electronic component 110A, 110B. For example, metal layer 352 can contact the top side of each electronic component 110A, 110B and the top side of the encapsulant 320. In some examples, metal layer 352 can comprise or be referred to as a BSM (Back Side Metal) plating layer, a conductive layer, or a conductive film. In various examples, the metal layer 352 can be provided by electrolytic plating, electroless plating, sputtering, physical vapor deposition (PVD), vacuum metallization, transfer metallization, or metallizing paint, or a combination thereof. In some examples, the metal layer 352 can be made of copper, (Cu), gold (Au), and/or silver (Ag). In various examples, the metal layer 352 can comprise a multi-layer metal stack. For example, the metal layer 352 can comprise an adhesion layer (e.g., Ti or TiW) applied on the top side of each electronic components 110A, 110B and/or the top side of the encapsulant 320, a barrier layer (e.g., Ni or NiV) applied on the adhesion layer, and a wetting layer (e.g., Au or Ag) applied on barrier layer. In some examples, the thickness of metal layer 352 can range from approximately 0.3 μm to approximately 10 μm.

While depicted as a metal layer 352 in FIG. 6B, the stiffener 350 in other examples can comprise a lid similar to the stiffener 250. Further, FIG. 6B depicts the encapsulant 320 underfilling the electronic module 101A and/or the electronic components 340. However, in some examples, the electronic device 300 can include a separate underfill similar to the underfill 220 of FIG. 5 that underfills the electronic module 101A and/or the electronic components 340.

Conversely, while FIG. 5 lacks an encapsulant, the electronic device 200 of FIG. 5 can include an encapsulant that encapsulates the electronic module 101 and electronic components 240 in a manner similar to the encapsulant 320 of FIG. 6B. Moreover, such an encapsulant can be used to underfill the electronic module 101 and/or the electronic components 340 instead of a separate underfill 220 as shown. Further, while FIG. 5 depicts the stiffener 250 comprising a lid, the stiffener 250 of FIG. 5 in other examples can comprise a metal layer similar to the metal layer 352 of FIG. 6B.

The present disclosure includes reference to certain examples; however, it will be understood by those skilled in the art that various changes can be made, and equivalents can be substituted without departing from the scope of the disclosure. In addition, modifications can be made to the disclosed examples without departing from the scope of the present disclosure. Therefore, it is intended that the present disclosure not be limited to the examples disclosed, but that the disclosure will include all examples falling within the scope of the appended claims.

What is claimed is:

1. An electronic device, comprising:
a lower substrate comprising a lower substrate top side and a lower substrate bottom side;
an upper substrate comprising an upper substrate top side and an upper substrate bottom side;
a bridge comprising a bridge die, bridge through-interconnects that pass through the bridge die, a bridge signal distribution structure along a top side of the bridge die and coupled to upper ends of the bridge through-interconnects, bridge upper interconnects along a top side of the bridge signal distribution structure, bridge lower interconnects along a bottom side of the bridge die, and a bridge mold layer that covers the bottom side of the bridge die and laterally surrounds the bridge lower interconnects;
a first electronic component electrically coupled to the bridge signal distribution structure via the upper substrate; and
a second electronic component electrically coupled to first electronic component via the upper substrate and the bridge signal distribution structure.

2. The electronic device of claim 1, wherein the bridge upper interconnects, the bridge signal distribution structure, the bridge through-interconnects, and the bridge lower interconnects electrically couple the first electronic component and the second electronic component to the lower substrate.

3. The electronic device of claim 1, comprising internal interconnects that electrically couple the first electronic component and the second electronic component to the lower substrate.

4. The electronic device of claim 3, comprising:
first component interconnects that couple the first electronic component and the second electronic component to the bridge via the upper substrate; and
second component interconnects that couple the first electronic component and the second electronic component to the internal interconnects via the upper substrate.

5. The electronic device of claim 3, comprising a lower encapsulant that contacts and laterally surrounds the bridge and the internal interconnects.

6. The electronic device of claim 5, comprising an upper encapsulant that contacts and laterally surrounds the first electronic component and the second electronic component.

7. The electronic device of claim 6, wherein the bridge mold layer, the lower encapsulant, and the upper encapsulant are formed from a same mold material.

8. The electronic device of claim 5, wherein the bridge mold layer and the lower encapsulant are formed from a same mold material.

9. The electronic device of claim 1, wherein a bottom side of the bridge mold layer contacts the lower substrate top side.

10. The electronic device of claim 1, wherein the bridge comprises a lower signal distribution structure between the bottom side of the bridge die and the bridge mold layer.

11. The electronic device of claim 1, wherein the bridge comprises one or more integrated circuit devices.

12. The electronic device of claim 1, comprising a second bridge comprising:
a second bridge die;
second bridge through-interconnects that pass through the second bridge die;
second bridge upper interconnects along a top side of the second bridge die;
second bridge lower interconnects along a bottom side of the second bridge die; and
a second bridge mold layer that covers the bottom side of the second bridge die and laterally surrounds the second bridge lower interconnects;
wherein the second bridge die electrically couples the second electronic component to the lower substrate; and
wherein the second bridge die not electrically coupled to the first electronic component.

13. The electronic device of claim 1, comprising:
a first underfill between the upper substrate top side and a bottom side of the first electronic component; and
a second underfill between the upper substrate top side and a bottom side of the second electronic component.

14. The electronic device of claim 1, comprising:
a device substrate comprising a device substrate top side and a device substrate bottom side; and
wherein the lower substrate bottom side is coupled to the device substrate top side.

15. The electronic device of claim 14, comprising a stiffener that covers the first electronic component and the second electronic component.

16. The electronic device of claim 15, wherein the stiffener comprises a lid coupled to the device substrate top side.

17. The electronic device of claim 15, wherein the stiffener comprises a metal layer that contacts and covers a top side of the first electronic component and that contacts and covers a top side of the second electronic component.

18. A method of providing an electronic device, the method comprising:
providing a bridge comprising a bridge die, bridge through-interconnects that pass through the bridge die, a bridge signal distribution structure along a top side of the bridge die and coupled to upper ends of the bridge through-interconnects, bridge upper interconnects along a top side of the bridge signal distribution structure, bridge lower interconnects along a bottom side of the bridge die, a bridge mold layer that covers the bottom side of the bridge die and laterally surrounds the bridge lower interconnects, and a bridge die attach film along a bottom side of the bridge mold layer;
encapsulating the bridge in a lower encapsulant comprising a lower encapsulant bottom side and a lower encapsulant top side, wherein the lower encapsulant covers the bridge upper interconnects;
removing an upper portion of the lower encapsulant to expose upper ends of the bridge upper interconnects;
providing an upper substrate over the lower encapsulant such that a upper substrate conductive structure is electrically coupled to the upper ends of the bridge upper interconnects;
providing a first electronic component and a second electronic component on the upper substrate such that the first electronic component and the second electronic component are electrically coupled to each other via the upper substrate and the bridge;
removing a lower portion of the lower encapsulant, the bridge die attach film, a lower portion of the bridge mold layer, and a lower portion of the bridge lower interconnects to expose lower ends of the bridge lower interconnects; and
providing a lower substrate covering a bottom side of the lower encapsulant and electrically coupled to the lower ends of the bridge lower interconnects.

19. The method of claim 18, wherein the bridge mold layer covers the lower ends of the bridge lower interconnects.

20. The method of claim 18, comprising:
coupling the bottom side of the lower substrate to a top side of device substrate; and
providing a stiffener over the first electronic component and the second electronic component.
